(19) United States
(12) Patent Application Publication
(10) Pub. No.: US 2022/0302348 A1
(43) Pub. Date: Sep. 22, 2022

(54) Micro LED chip, display panel and method for welding micro LED chip

(71) Applicant: CHONGQING KONKA PHOTOELECTRIC TECHNOLOGY RESEARCH INSTITUTE CO., LTD., Chongqing (CN)

(72) Inventor: CHING-CHUNG CHEN, Chongqing (CN)

(21) Appl. No.: 17/058,660

(22) PCT Filed: Dec. 10, 2019
(86) PCT No.: PCT/CN2019/124181

§ 371 Date: Nov. 25, 2020

(51) Int. Cl. H01L 33/38; H01L 33/62; H01L 23/00; H01L 33/42

(52) U.S. Cl. CPC H01L 33/382; H01L 33/62; H01L 24/81; H01L 33/42; H01L 33/32

(57) ABSTRACT

The present disclosure relates to a Micro LED chip, a display panel and a method for welding the Micro LED chip. The Micro LED chip includes an N-type semiconductor layer, a P-type semiconductor layer, an N-type electrode and a P-type electrode, wherein the N-type electrode is arranged on the N-type semiconductor layer, and the P-type electrode is arranged on the P-type semiconductor layer; the N-type electrode includes a first path, the first path penetrating the N-type electrode; and the P-type electrode includes a second path, the second path penetrating the P-type electrode.

### TECHNICAL FIELD

The present disclosure relates to the technical field of Micro LED, in particular to a Micro LED chip, a display panel and a method for welding the Micro LED chip.

### BACKGROUND

As a new-generation display technology, the Micro LED is higher in luminance, higher in luminous efficiency, and lower in power consumption compared with the existing OLED technology. The displayer manufactured with the Micro LED has the advantages of better stability, longer service life, lower running temperature, etc., also inherits the advantages of low power consumption, high color saturation, rapid response speed, strong contrast, etc. from the existing LED, thereby having a great application prospect.

At present, during a manufacturing process of the Micro LED display, it is necessary to weld two electrodes of the Micro LED to a display panel so as to achieve good electrical contacts between the two electrodes of the Micro LED and the corresponding electrical contact points of the display panel. As shown in FIG. 1, the Micro LED includes an N-type semiconductor layer 11, an active layer 12, a P-type semiconductor layer 13, an N-type electrode 14 and a P-type electrode 15. When the two electrodes of the Micro LED are welded to the display panel, it is necessary to heat solder between the electrode of the Micro LED and the electrical contact point of the display panel to a certain temperature and melt the solder through conduction of heat, so as to achieve the purpose of welding. However, if the display panel is directly heated, a component on the display panel may be damaged. With the current LED structure, the Micro LED can only be welded to the display panel by directly heating the display panel.

Therefore, the existing technology needs to be improved.

### SUMMARY

A technical problem to be solved by the present disclosure is to provide a Micro LED chip, a display panel and a method for welding the Micro LED chip. The Micro LED chip may be welded to the display panel in other manners, for example, a laser beam may be used to pass through a first path and a second path to melt solder, and the solder connects the Micro LED chip to the display panel after condensed, thereby avoiding damage, caused by directly heating the display panel in a welding process, to a component on the display panel.

In a first aspect, an embodiment of the present disclosure provides the Micro LED chip, and the Micro LED chip includes an N-type semiconductor layer, a P-type semiconductor layer, an N-type electrode and a P-type electrode. The N-type electrode is arranged on the N-type semiconductor layer, and the P-type electrode is arranged on the P-type semiconductor layer. The N-type electrode includes a first path, and the first path penetrating the N-type electrode. The P-type electrode includes a second path, and the second path penetrating the P-type electrode. The first path and the second path are configured to allow a laser beam to pass therethrough.

In an embodiment, the Micro LED chip includes a conduction material being arranged in the first path or the second path.

In an embodiment, the Micro LED chip includes a conduction material of the same type being arranged in the first path and the second path.

In an embodiment, the Micro LED chip includes a first conduction material being arranged in the first path, a second conduction material being arranged in the second path, and the first conduction material being different from the second conduction material.

In an embodiment, the Micro LED chip includes an active layer, the active layer being arranged between the N-type semiconductor layer and the P-type semiconductor layer.

In an embodiment, the N-type semiconductor layer includes an N-type gallium nitride material. In an embodiment, the P-type semiconductor layer includes a P-type gallium nitride material. In an embodiment, the active layer includes a gallium nitride material.

In a second aspect, an embodiment of the present disclosure provides a display panel, and the display panel is provided with the Micro LED chip mentioned above through welding. The solder and the Micro LED chip are sequentially arranged above one end surface of the display panel, and the solder is illuminated and molten by a laser beam passing through a first path and a second path, and connects the Micro LED chip to the display panel after the solder is condensed.

In a third aspect, an embodiment of the present disclosure provides a method for welding the Micro LED chip, and the method is used for welding the Micro LED chip mentioned above to the display panel. The method includes:

the solder is arranged on a surface of an N-type electrode and a surface of a P-type electrode of the Micro LED chip, and the Micro LED chip provided with the solder is transferred to a position above the display panel; and

after the Micro LED chip is transferred to the position above the display panel, a laser beam is controlled to pass through a first path and a second path to illuminate the solder, so as to melt the solder and connect the Micro LED chip to the display panel after the solder is condensed.

Compared with the prior art, the embodiment of the present disclosure has the following advantages:

according to the Micro LED chip provided by the embodiment of the present disclosure, the Micro LED chip includes the N-type semiconductor layer, the P-type semiconductor layer, the N-type electrode and the P-type electrode, wherein the N-type electrode is arranged on the N-type semiconductor layer, and the P-type electrode is arranged on the P-type semiconductor layer; the N-type electrode includes the first path, the first path penetrating the N-type electrode; and the P-type electrode includes the second path, the second path penetrating the P-type electrode, and the first path and the second path being configured to allow the laser beam to pass therethrough. The Micro LED chip with the first path and the second path in the present disclosure can be welded to the display panel in other manners, for example, the laser beam may be used to pass through the first path and the second path to melt the solder, and the solder connects the Micro LED chip to the display panel after condensed, thereby avoiding the damage, caused by directly heating the display panel in the welding process, to the component on the display panel.

### BRIEF DESCRIPTION OF THE DRAWINGS

In order to more clearly illustrate technical solutions in the embodiments of the present disclosure or in the prior art, a brief introduction to the accompanying drawings required for the description of the embodiments or the prior art will be provided below.

FIG. 1 is a schematic structural diagram of a Micro LED in a related art;

FIG. 2 is a schematic structural diagram of a Micro LED chip in an embodiment of the present disclosure;

FIG. 3 is schematic structural diagram of a display panel in an embodiment of the present disclosure;

FIG. 4 is a schematic flowchart of a method for welding the Micro LED chip in an embodiment of the present disclosure;

FIG. 5 is a schematic diagram for transferring the Micro LED chip to a position above the display panel in an embodiment of the present disclosure;

FIG. 6 is a schematic diagram for a welding process of the Micro LED chip in an embodiment of the present disclosure; and

FIG. 7 is a schematic diagram of the Micro LED chip subjected to welding in an embodiment of the present disclosure.

### DETAILED DESCRIPTION OF THE EMBODIMENTS

In order to enable those skilled in the art to better understand solutions of the present disclosure, the technical solutions in embodiments of the present disclosure will be described below clearly and comprehensively in conjunction with accompanying drawings of the embodiments of the present disclosure. Apparently, the embodiments described are merely some of the embodiments of the present disclosure rather than all of them. Based on the embodiments of the present disclosure, all other embodiments obtained by those of ordinary skilled in the art without making creative efforts fall within the scope of protection of the present disclosure.

The inventor discovers through research that when two electrodes of a Micro LED chip are welded to a display panel, it is necessary to heat solder between the electrode of the Micro LED chip and an electrical contact point of the display panel to a certain temperature and melt the solder through conduction of heat, so as to achieve the purpose of welding. However, if the display panel is directly heated, a component on the display panel may be damaged, thereby causing a manufactured display to malfunction and shortening a service life accordingly.

To solve the problem mentioned above, a Micro LED chip whose N-type electrode and P-type electrode are internally provided with a first path and a second path respectively in the embodiment of the present disclosure may be welded to the display panel in other manners, for example, the laser beam may be used to pass through the first path and the second path to melt the solder, and the solder connects the Micro LED chip to the display panel after condensed, thereby avoiding the damage, caused by directly heating the display panel in a welding process, to the component on the display panel.

Various non-restrictive embodiments of the present disclosure will be described in details below in conjunction with accompanying drawings.

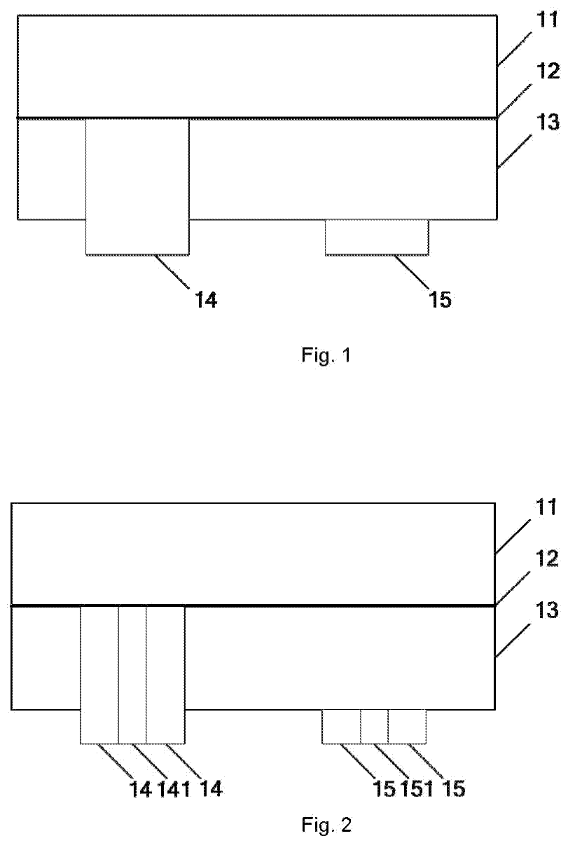

An embodiment of the present disclosure provides a Micro LED chip, and as shown in FIG. 2, the Micro LED chip includes an N-type semiconductor layer 11, a P-type semiconductor layer 13, an N-type electrode 14 and a P-type electrode 15.

The N-type electrode 14 is arranged on the N-type semiconductor layer 11, and the P-type electrode 15 is arranged on the P-type semiconductor layer 13. The N-type electrode 14 includes a first path 141, the first path 141 penetrating the N-type electrode 14. The P-type electrode 15 includes a second path 151, the second path 151 penetrating the P-type electrode 15.

In an optional manner of the embodiment of the present disclosure, the first path 141 and the second path 151 are configured to allow a laser beam to pass therethrough. The laser beam is used to directly heat solder to avoid damage to a component on a display panel in a process of directly heating the display panel and melting the solder. In addition, in this embodiment of the present disclosure, the N-type electrode and the P-type electrode are internally provided with the first path and the second path respectively. The first path and the second path are configured to allow the laser beam to pass through the first path and the second path. After passing through the first path and the second path, the laser beam heats the solder between the Micro LED chip and the display panel, and the solder is heated and molten and connects the Micro LED chip to the display panel after condensed.

In this embodiment of the present disclosure, the first path and the second path may be internally provided with a high-transmittance material and/or a high-temperature-resistant material, through which the laser beam may smoothly penetrate the N-type electrode and the P-type electrode to illuminate the solder. Therefore, with respect to the first path and the second path, there are several implementations below in this embodiment of the present disclosure:

1. no conduction material is arranged in the first path or the second path (that is, air serves as a conduction material);

2. a conduction material is arranged in the first path or the second path, that is, no conduction material is arranged in the first path (that is, air serves as the conduction material) but the conduction material is arranged in the second path, or the conduction material is arranged in the first path and no conduction material is arranged in the second path (that is, air serves as the conduction material);

3. the first path and the second path are arranged with the same type of conduction material; and

4. a first conduction material is arranged in the first path, a second conduction material is arranged in the second path, and the first conduction material is different from the second conduction material.

By arranging the conduction material in the path, the conduction material mentioned above has high transmittance, thereby improving conduction efficiency of the laser beam to make the laser beam rapidly and accurately illuminate the solder, and increasing a welding speed. When the conduction material mentioned above has good heat conductivity, head dissipation efficiency during working of the Micro LED chip mentioned above may be further increased, and a heat dissipation effect of the Micro LED chip may be further improved.

In another optional manner of this embodiment of the present disclosure, a heating material with a limited heating time can be added in the first path and the second path. When the Micro LED chip is welded to the display panel, the heating materials in the first path and the second path in the electrodes of the Micro LED chip may heat and melt the solder, and the solder connects the Micro LED chip to the display panel after condensed.

In another optional manner of this embodiment of the present disclosure, a proper amount of solder can be added in the first path and the second path, and the solder in the first path and the second path are molten through a heat conduction apparatus or a heat conduction material which has a cross sectional area identical to that of the first path and that of the second path. Alternatively, a proper amount of solder is added in the first path and the second path, the laser beam is controlled to pass through the first path and the second path to illuminate the solder in the first path and the second path so as to melt the solder.

In this embodiment of the present disclosure, as shown in FIG. 2, the chip further includes an active layer 12, and the active layer 12 is arranged between the N-type semiconductor layer 11 and the P-type semiconductor layer 13.

In this embodiment of the present disclosure, the N-type semiconductor layer is mainly composed of an N-type gallium nitride material, the P-type semiconductor layer is mainly composed of a P-type gallium nitride material, and the active layer is mainly composed of a gallium nitride material.

In this embodiment of the present disclosure, the display panel may further include a PCB, and the Micro LED is fixed to the PCB.

Through the Micro LED chip with the first path and the second path in this embodiment of the present disclosure, the laser beam can pass through the first path and the second path to melt the solder, and the solder connects the Micro LED chip to the display panel after condensed, thereby avoiding damage, caused by directly heating the display panel in a welding process, to a component on the display panel.

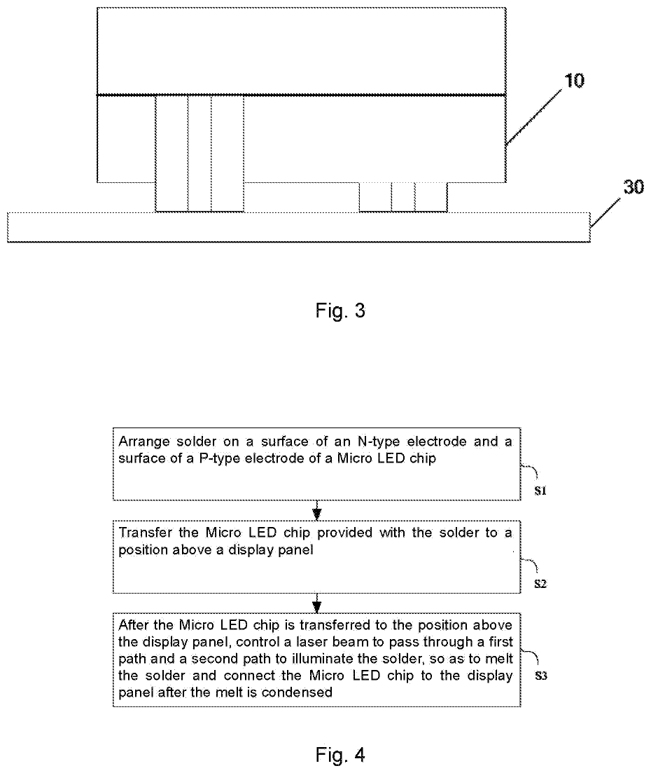

An embodiment of the present disclosure provides a display panel, as shown in FIG. 3. The display panel 30 is provided with the Micro LED chip 10 mentioned above through welding, solder and the Micro LED chip 10 are sequentially arranged above one end surface of the display panel 30, and the solder is illuminated and molten by a laser beam passing through a first path 141 and a second path 151, and connects the Micro LED chip 10 to the display panel 30 after condensed.

In a particular embodiment of the present disclosure, the display panel includes a PCB, and the Micro LED 10 mentioned above is welded to the PCB. Particularly, the solder 20 and the Micro LED chip 10 are sequentially arranged above one end surface of the PCB, and the solder 20 is illuminated and molten by the laser beam passing through the first path 141 and the second path 151 and connects the Micro LED chip 10 to the PCB after condensed.

The embodiment of the present disclosure further provides a method for welding a Micro LED chip, as shown in FIG. 4, the Micro LED chip 10 is welded to a display panel 30 through the method, and the method includes:

S1, the solder 20 is arranged on a surface of an N-type electrode 14 and a surface of a P-type electrode 15 of the Micro LED chip;

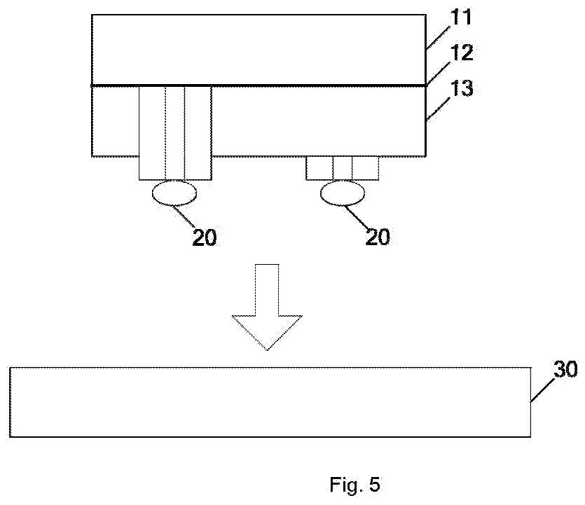

S2, the Micro LED chip provided with the solder 20 is transferred to a position above the display panel 30, as shown in FIG. 5; and

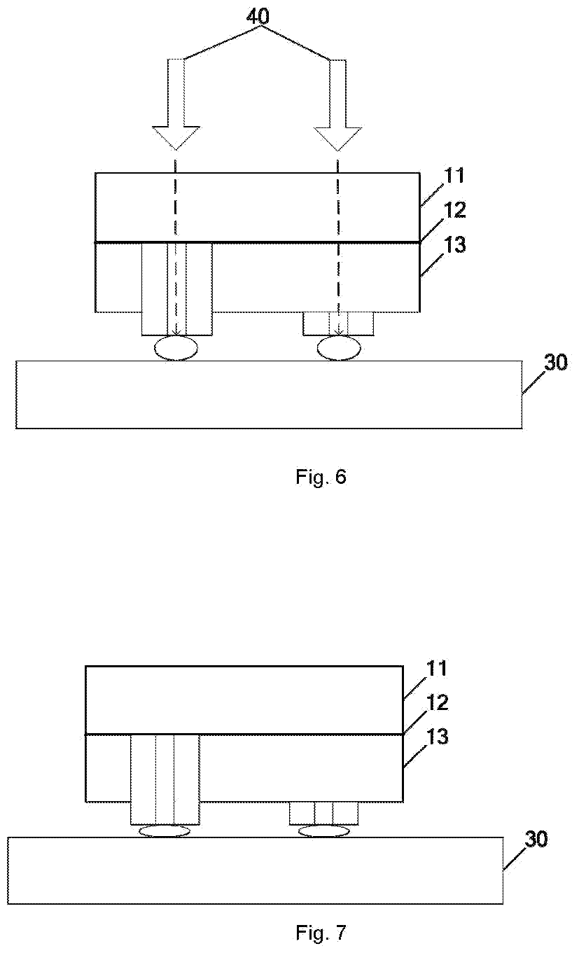

S3, after the Micro LED chip is transferred to the position above the display panel 30, a laser beam 40 is controlled to pass through a first path and a second path to illuminate the solder, as shown in FIG. 6, so as to melt the solder and connect the Micro LED chip to the display panel 30 after the solder is condensed, as shown in FIG. 7.

In this embodiment of the present disclosure, the solder may be arranged on the surface of the N-type electrode and the surface of the P-type electrode of the Micro LED chip, or the solder may be arranged at a position, to which the Micro LED chip is welded, on the display panel.

In this embodiment of the present disclosure, the Micro LED chip is transferred to a position right above the welding position of the display panel, the position right below the Micro LED chip 10 is sequentially provided with the solder 20 and the display panel 30, and the laser beam 40 is controlled to simultaneously pass through the first path and the second path. After the laser beam melts the solder, the solder is in a state of liquid. Before the solder is condensed (the solder is still in the state of liquid), a position of the Micro LED chip may be adjusted, such that the Micro LED chip may be in electrical contact with the display panel, thereby avoiding the problems that bad contact or normal running incapacity is caused due to an error occurring in a welding position between the Micro LED chip and the display panel.

Through the method for welding the Micro LED chip to the display panel by the laser beam passing through the first path and the second path in the embodiment of the present disclosure, the laser beam can pass through the first path and the second path to melt the solder, the solder connects the Micro LED chip to the display panel after condensed, thereby avoiding damage, caused by directly heating the display panel in a welding process, to a component on the display panel.

Various technical features of the embodiments mentioned above may be arbitrarily combined. To simplify description, all possible combinations of the various features of the embodiments mentioned above are not described. However, if only the combinations of these technical features do not conflict, they shall be considered to be within the scope of description of the present invention.

The embodiments mentioned above are merely several embodiments of the present disclosure, and are specifically described in details, but cannot be interpreted as limiting the scope of the patent for the invention as a result. It shall be noted that for those of ordinary skill in the field, they may make several transformations and improvements on the premise of not deviating from the conception of the present disclosure, and these transformations and improvements shall fall within the scope of protection of the disclosure. Hence, the scope of protection of the present disclosure shall be subject to the appended claims.

1. A Micro LED chip, comprising:
an N-type semiconductor layer, a P-type semiconductor layer, an N-type electrode and a P-type electrode, wherein the N-type electrode is arranged on the N-type semiconductor layer, and the P-type electrode is arranged on the P-type semiconductor layer;
the N-type electrode comprises a first path, and the first path penetrating the N-type electrode; and
the P-type electrode comprises a second path, and the second path penetrating the P-type electrode.

2. The Micro LED chip as claimed in claim 1, wherein the Micro LED chip comprises:
a conduction material being arranged in the first path or the second path.

3. The Micro LED chip as claimed in claim 1, wherein the Micro LED chip comprises:
a conduction material of the same type being arranged in the first path and the second path.

4. The Micro LED chip as claimed in claim 1, wherein the Micro LED chip comprises:
a first conduction material being arranged in the first path, and a second conduction material being arranged in the second path, wherein the first conduction material being different from the second conduction material.

5. The Micro LED chip as claimed in claim 1, wherein the Micro LED chip comprises:
an active layer, the active layer being arranged between the N-type semiconductor layer and the P-type semiconductor layer.

6. The Micro LED chip as claimed in claim 1, wherein the N-type semiconductor layer comprises an N-type gallium nitride material.

7. The Micro LED chip as claimed in claim 1, wherein the P-type semiconductor layer comprises a P-type gallium nitride material.

8. The Micro LED chip as claimed in claim 1, wherein the active layer comprises a gallium nitride material.

9. A display panel, wherein the display panel is provided with the Micro LED chip as claimed in claim 1 through welding;
solder and the Micro LED chip are sequentially arranged above one end surface of the display panel; and
the solder is illuminated and molten by a laser beam passing through a first path and a second path, and connects the Micro LED chip to the display panel after the solder is condensed.

10. A method for welding a Micro LED chip, wherein the Micro LED chip as claimed in claim 1 is welded to a display panel, and the method comprises:
arranging solder on a surface of an N-type electrode and a surface of a P-type electrode of the Micro LED chip;
transferring the Micro LED chip provided with the solder to a position above the display panel; and
after the Micro LED chip is transferred to the position above the display panel, controlling a laser beam to pass through a first path and a second path to illuminate the solder, so as to melt the solder and connect the Micro LED chip to the display panel after the solder is condensed.

11. A display panel, wherein the display panel is provided with the Micro LED chip as claimed in claim 2 through welding;
solder and the Micro LED chip are sequentially arranged above one end surface of the display panel; and
the solder is illuminated and molten by a laser beam passing through a first path and a second path, and connects the Micro LED chip to the display panel after the solder is condensed.

12. A display panel, wherein the display panel is provided with the Micro LED chip as claimed in claim 3 through welding;
solder and the Micro LED chip are sequentially arranged above one end surface of the display panel; and
the solder is illuminated and molten by a laser beam passing through a first path and a second path, and connects the Micro LED chip to the display panel after the solder is condensed.

13. A display panel, wherein the display panel is provided with the Micro LED chip as claimed in claim 4 through welding;
solder and the Micro LED chip are sequentially arranged above one end surface of the display panel; and
the solder is illuminated and molten by a laser beam passing through a first path and a second path, and connects the Micro LED chip to the display panel after the solder is condensed.

14. A display panel, wherein the display panel is provided with the Micro LED chip as claimed in claim 5 through welding;
solder and the Micro LED chip are sequentially arranged above one end surface of the display panel; and
the solder is illuminated and molten by a laser beam passing through a first path and a second path, and connects the Micro LED chip to the display panel after the solder is condensed.

15. A display panel, wherein the display panel is provided with the Micro LED chip as claimed in claim 6 through welding;
solder and the Micro LED chip are sequentially arranged above one end surface of the display panel; and
the solder is illuminated and molten by a laser beam passing through a first path and a second path, and connects the Micro LED chip to the display panel after the solder is condensed.

16. A display panel, wherein the display panel is provided with the Micro LED chip as claimed in claim 7 through welding;
solder and the Micro LED chip are sequentially arranged above one end surface of the display panel; and
the solder is illuminated and molten by a laser beam passing through a first path and a second path, and connects the Micro LED chip to the display panel after the solder is condensed.

17. A display panel, wherein the display panel is provided with the Micro LED chip as claimed in claim 8 through welding;
solder and the Micro LED chip are sequentially arranged above one end surface of the display panel; and
the solder is illuminated and molten by a laser beam passing through a first path and a second path, and connects the Micro LED chip to the display panel after the solder is condensed.

18. A method for welding a Micro LED chip, wherein the Micro LED chip as claimed in claim 2 is welded to a display panel, and the method comprises:
arranging solder on a surface of an N-type electrode and a surface of a P-type electrode of the Micro LED chip;
transferring the Micro LED chip provided with the solder to a position above the display panel; and
after the Micro LED chip is transferred to the position above the display panel, controlling a laser beam to pass through a first path and a second path to illuminate the solder, so as to melt the solder and connect the Micro LED chip to the display panel after the solder is condensed.

19. A method for welding a Micro LED chip, wherein the Micro LED chip as claimed in claim 3 is welded to a display panel, and the method comprises:
arranging solder on a surface of an N-type electrode and a surface of a P-type electrode of the Micro LED chip;
transferring the Micro LED chip provided with the solder to a position above the display panel; and
after the Micro LED chip is transferred to the position above the display panel, controlling a laser beam to pass through a first path and a second path to illuminate the solder, so as to melt the solder and connect the Micro LED chip to the display panel after the solder is condensed.

20. A method for welding a Micro LED chip, wherein the Micro LED chip as claimed in claim 4 is welded to a display panel, and the method comprises:
arranging solder on a surface of an N-type electrode and a surface of a P-type electrode of the Micro LED chip;
transferring the Micro LED chip provided with the solder to a position above the display panel; and
after the Micro LED chip is transferred to the position above the display panel, controlling a laser beam to pass through a first path and a second path to illuminate the solder, so as to melt the solder and connect the Micro LED chip to the display panel after the solder is condensed.
